(19) United States
(12) Patent Application Publication
(10) Pub. No.: US 2010/0051103 A1
(43) Pub. Date: Mar. 4, 2010

(54) CASING OF ELECTRONIC DEVICE

(76) Inventors: Chien-An CHEN, Taipei City (TW); Shun-Wen Lin, Taipei City (TW); Tien-Chun Tseng, Taipei City (TW)

Correspondence Address: Muncy, Geissler, Olds & Lowe, PLLC, P.O. BOX 1364, FAIRFAX, VA, 22038-1364, US

(21) Appl. No.: 12/547,993

(22) Filed: Aug. 26, 2009

(30) Foreign Application Priority Data
Aug. 27, 2008 (TW) 097132703

(51) Int. Cl. H01L 31/0203

(52) U.S. Cl. 136/259

(57) ABSTRACT

A casing of an electronic device is located at an outermost layer of the electronic device and includes a photoelectric conversion film and a casing body. The photoelectric conversion film has an organic material. The casing body is used as a base plate of the photoelectric conversion film which is formed at the casing body.

### CROSS REFERENCE TO RELATED APPLICATIONS

This Non-provisional application claims priority under 35 U.S.C. §119(a) on Patent Application No(s). 097132703 filed in Taiwan, Republic of China on Aug. 27, 2008, the entire contents of which are hereby incorporated by reference.

### BACKGROUND OF THE INVENTION

1. Field of Invention

The invention relates to an electronic device and a casing thereof and, more particularly, to a casing of an electronic device having a photoelectric conversion film.

2. Related Art

Solar energy is pollution-free, and easy to obtain. Therefore, the solar energy becomes one of important substitute energy. A solar cell using the solar energy is a photoelectric element. After the solar cell is lit by the sunlight, the solar cell converts light into electricity.

The solar cell has a plurality of types. At present, mass-produced commercialized solar cells mainly include monocrystalline silicon solar cells, polycrystalline silicon solar cells, semiconductor compound solar cells, and amorphous silicon solar cells. The monocrystalline silicon and the polycrystalline silicon solar cells need a high purity silicon material to be used as a base plate. Therefore, the manufacturing process is complex and cost is high. Further, the amorphous silicon and the semiconductor compound solar cells need a high temperature manufacturing process. Therefore, they need to be formed at a base plate which is resistant to high temperatures. As far as a plurality of consumer electronic devices using the solar cells and having casing bodies mostly made of plastic is considered, the solar cells need to be made independently and additionally then to be assembled with the electronic devices. Thus, the manufacture takes time, and the cost and price of the device increase, thereby reducing the application value.

### SUMMARY OF THE INVENTION

This invention provides a casing of an electronic device. A casing body of the casing is used as a base plate of a photoelectric conversion film, and the casing of the electronic device is directly used as a photoelectric element, further to simplify the manufacturing process and to reduce manufacturing cost to improve the prior art.

According to one aspect of the invention, the casing includes a photoelectric conversion film and a casing body. The photoelectric conversion film has an organic material. The casing body is used as a base plate of the photoelectric conversion film, and the photoelectric conversion film is formed at the casing body.

According to one aspect of the invention, the casing includes an electronic element. The casing has a photoelectric conversion film and a casing body. The photoelectric conversion film has an organic material. The casing body is used as a base plate of the photoelectric conversion film, and the photoelectric conversion film is formed at the casing body. The electronic element is disposed in the casing body.

In one embodiment of the invention, the casing body may be transparent to light or lightproof.

In one embodiment of the invention, the casing body may be made of plastic, ceramics, glass, quartz, metal, alloy, or a combination thereof.

In one embodiment of the invention, the photoelectric conversion film may have a first electrode layer, a second electrode layer, and a photoelectric conversion layer located between the first electrode layer and the second electrode layer.

In one embodiment of the invention, the first electrode layer may be located on the casing body.

In one embodiment of the invention, the photoelectric conversion layer may be a single layer or a double layer made of a donor material and an acceptor material.

In one embodiment of the invention, the photoelectric conversion film may be formed at one side or two sides of the casing body by printing, spreading, spraying, sputtering, evaporating, transfer printing, or a combination thereof.

In one embodiment of the invention, an anti-reflecting layer may be disposed at the photoelectric conversion film, at the casing body, or between the photoelectric conversion film and the casing body.

To sum up, in the casing according to the invention, the casing body is used as a base plate, and the photoelectric conversion film having the organic material is formed at the casing body. Since the photoelectric conversion film includes the organic material, the photoelectric conversion film can be formed at one side or two sides of the casing body by a low temperature and simple manufacturing process such as printing, spreading, spraying, sputtering, evaporating, transfer printing, or a combination thereof. Thus, the casing of the electronic device is directly used as a photoelectric element, further to simplify the manufacturing process and to reduce manufacturing cost. In addition, since the casing body of the casing is used as a base plate of the photoelectric conversion film, a base plate originally needed can be omitted, further to reduce the cost and to decrease thickness of the casing.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing an electronic device according to one preferred embodiment of the invention;

FIG. 1B is a sectional schematic diagram along a section line A-A in FIG. 1A;

FIG. 2 is a partial schematic diagram showing another casing of an electronic device according to one preferred embodiment of the invention;

FIG. 3 is a partial schematic diagram showing another casing of an electronic device according to one preferred embodiment of the invention;

FIG. 4 is a partial schematic diagram showing another casing of an electronic device according to one preferred embodiment of the invention; and

FIG. 5 is a partial schematic diagram showing anther casing of an electronic device according to one preferred embodiment of the invention.

### DETAILED DESCRIPTION OF THE INVENTION

### A First Embodiment

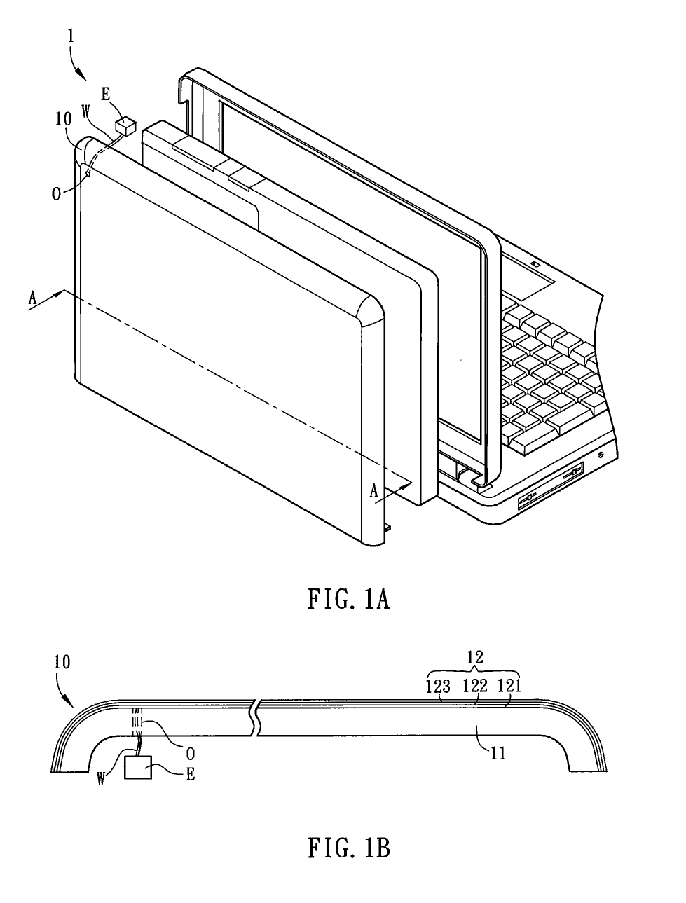

FIG. 1A is a schematic diagram showing an electronic device 1 according to one preferred embodiment of the invention. An electronic device 1 includes a casing 10. The invention does not limit the type of the electronic device 1. The electronic device 1 may be a communication device, a notebook computer, a digital camera, a media player, or an electronic device having the above element. In this embodiment, the electronic device 1 is a notebook computer.

The casing 10 includes a photoelectric conversion film 12, a casing body 11, and an electronic element E. In this embodiment, an outer casing body of a screen of a notebook computer as the casing 10 is taken for example. The electronic element E is disposed in the casing 10. The invention does not limit the type of the electronic element E. The electronic element E may be a circuit board, a screen, an active element, a passive element, a chip, or any other electronic element disposed in the casing 10.

FIG. 1B is a sectional schematic diagram along a sectional line A-A in FIG. 1A. Please refer to FIG. 1B. The photoelectric conversion film 12 has an organic material. The casing body 11 is used as a base plate of the photoelectric conversion film 12, and the photoelectric conversion film 12 is formed at the casing body 11. Since the photoelectric conversion film 12 has the organic material, in this embodiment of the invention, the photoelectric conversion film 12 can be formed at one side or two sides of the casing body 11 by a low temperature and simple manufacturing process such as printing (such as screen printing), spreading (such as spin spreading), spraying (such as ink jet printing), sputtering (such as low temperature sputtering), evaporating, transfer printing, or a combination thereof. Thus, the casing 10 of the electronic device 1 is directly used as a photoelectric element, further to simplify the manufacturing process and to reduce manufacturing cost. In this embodiment, the photoelectric conversion film 12 is formed at one side of the casing body 11.

In the electronic device according to this embodiment of the invention, the casing body can be transparent to light or lightproof. In this embodiment, since light first passes through the photoelectric conversion film 12 and then reaches the casing body 11, the casing body 11 can be lightproof. The casing body 11 can be made of plastic, ceramics, glass, quartz, metal, alloy, or a combination thereof. The allowable processing temperature of the casing body 11 is different with the material of the casing body 11. Therefore, in this embodiment of the invention, different forming modes can be selected according to the materials of the casing body 11 and the photoelectric conversion film 12. In this embodiment, the casing body 11 is made of lightproof plastic.

In this embodiment, the photoelectric conversion film 12 has a first electrode layer 121, a second electrode layer 123, and a photoelectric conversion layer 122. The first electrode layer 121 is located on the casing body 11. The photoelectric conversion layer 122 is located between the first electrode layer 121 and the second electrode layer 123. The photoelectric conversion layer 122 is a single layer or a double layer made of a donor material and an acceptor material. That is, the donor material and the acceptor material can be mixed with each other or be disposed in a layered mode. In this embodiment, the donor material provides electron holes via excitation of the light, and the acceptor material provides electrons via excitation of the light.

The donor material and/or the acceptor material have at least one organic material. The organic material may be an organic polymer, an organic molecule, a dye, or a combination thereof. The organic polymer may be a conductive polymer, such as poly p-phenylene vinylene (PPV), polythiophene (PT), polypyrrole (PPy), polyaniline (Pan), other polymer such as poly 3-octylthiophene (P3OT) or derivative thereof. The dye may be an organic photosensitive dye including ruthenium complex series, phthalocyanine series, porphyrin series, chlorophyll or other derivative dyes.

In addition, the donor material and/or the acceptor material can further include an inorganic material such as TiO₂, Nb₂O₅, CdS, or a derivative of C₆₀. In addiction, the organic material may be mixed with the inorganic material to form a composite material.

When the photoelectric conversion layer 122 is excited by light to generate electron holes and electrons, the electron holes need to be instantly transmitted to a positive electrode, and the electrons need to be transmitted to a negative electrode. The first electrode layer 121 and the second electrode layer 123 can be a positive electrode and a negative electrode respectively or a negative electrode and a positive electrode respectively. In addition, the light transmittance of the first electrode layer 121 and the second electrode layer 123 needs to be considered. In this embodiment, since the light first passes through the second electrode layer 123 and then reaches the photoelectric conversion layer 122, the second electrode layer 123 needs to be transparent to light.

In this embodiment, the second electrode layer 123 can be a transparent and conductive metal oxide such as an indium-tin oxide (ITO), an indium-zinc oxide (IZO), an aluminum-zinc oxide (AZO), a gallium-zinc oxide (GZO), a zinc oxide (ZnO), or a stannum oxide (SnO₂.). The first electrode layer 121 may be an aluminum electrode, a silver electrode, a calcium electrode, or a molybdenum electrode. Since a power function of the electrode needs to be considered, the first electrode layer 121 and the second electrode layer 123 can be selected according to a practical situation. The first electrode layer 121 and the second electrode layer 123 may be formed by printing, spreading, spraying, sputtering, evaporating, transfer printing, or a combination thereof.

To increase photoelectric conversion efficiency, in this embodiment, an electron hole conducting layer and/or an electron conducting layer can be selectively disposed. The electron hole conducting layer and the electron conducting layer contact the photoelectric conversion layer 122, respectively, to improve conductivity of the electron holes and the electrons. In addition, since the photoelectric conversion film 12 is located at an outer side of the electronic device 1, the casing 10 can further include a protective layer (not shown). The protective layer is formed on the second electrode layer 123.

Please refer to FIG. 1A and FIG. 1B. In this embodiment, the electronic element E is disposed in the casing 10. An electricity storage unit of the photoelectric conversion film 12 as the electronic element E is taken for example. The electronic element E may include a capacitor, a charging battery, or a chip capable of storing electricity, and the electronic element E may be disposed on a circuit board. The photoelectric conversion film 12 and the electronic element E are disposed at two sides of the casing body 11, respectively, and they are electrically connected with each other. In this embodiment, the casing body 11 of the casing 10 has a through hole O, and the electronic element E is electrically connected with the first electrode layer 121 and the second electrode layer 123 via the through hole O. For example, the electronic element E may be connected with the first electrode layer 121 and the second electrode layer 123 by a wire W.

### A Second Embodiment

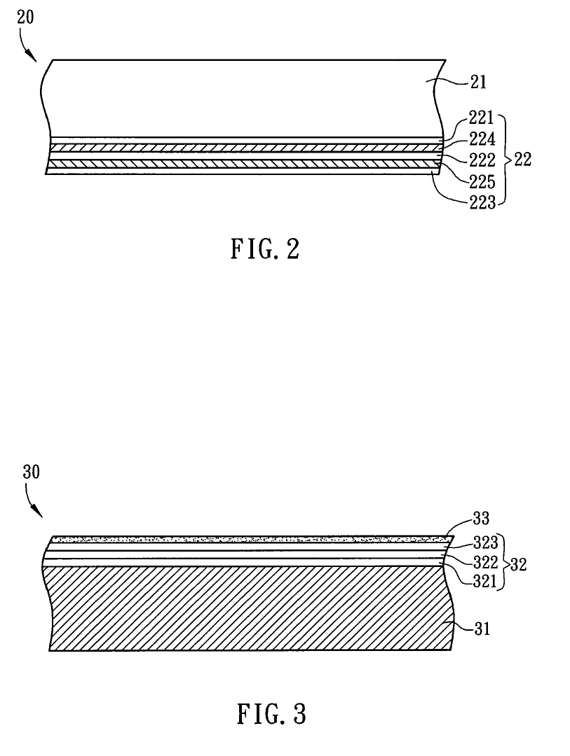

Please refer to FIG. 2. Another casing 20 of the electronic device 1 includes a photoelectric conversion film 22 and a casing body 21. The difference between this embodiment and the above embodiment is that the photoelectric conversion film 22 is formed at an inner side of the casing body 21. That is, light first passes through the casing body 21 and then reaches the photoelectric conversion film 22. The casing body 21 is made of a transparent and non-conductive material such as glass. The structures, materials, and manufacturing methods of a first electrode layer 221, a second electrode layer 223, and a photoelectric conversion layer 222 of the photoelectric conversion film 22 are described in detail in the photoelectric conversion film 12 provided by the above embodiment. Therefore, they are not described for a concise purpose.

The photoelectric conversion film 22 can further have an anti-reflecting layer 224 disposed at the photoelectric conversion film 22 and located between the first electrode layer 221 and the photoelectric conversion layer 222, to improve efficiency of the light passing through the first electrode layer 221 and to improve utilization of the light. The photoelectric conversion film 22 further includes an electron hole conducting layer 225 contacting the photoelectric conversion layer 222 to improve conductivity of the electron holes. The electron hole conducting layer 225 may be made of a conductive polymer, P3OT, PPV, PT, or a derivative thereof.

A Third Embodiment

Please refer to FIG. 3. Another casing 30 of the electronic device 1 includes a photoelectric conversion film 32 and a casing body 31. The difference between this embodiment and the above embodiments is that the photoelectric conversion film 32 includes a first electrode layer 321, a photoelectric conversion layer 322 and a second electrode layer 323, and the first electrode layer 321 located on the casing body 31. In this embodiment, a circuit board can be used as the first electrode layer 321 and the casing body 31. A conductive layer of the circuit board can be used as the first electrode layer 321. Thus, the manufacturing process of the first electrode layer 321 can be omitted. The circuit board may be a plastic circuit board, a glass circuit board, a ceramics circuit board, a metal circuit board, a resin circuit board, or a metal-core printed circuit board (MCPCB).

In addition, the casing 30 further includes a protective layer 33 which is insulating and is a waterproof polymer layer for preventing moisture or oxygen from penetrating into the photoelectric conversion film 32. In addition, the casing 30 can further include a microstructure disposed on the protective layer 33 or integrally formed with the protective layer 33. The microstructure may be a lens structure for adjusting a light route.

### A Fourth Embodiment

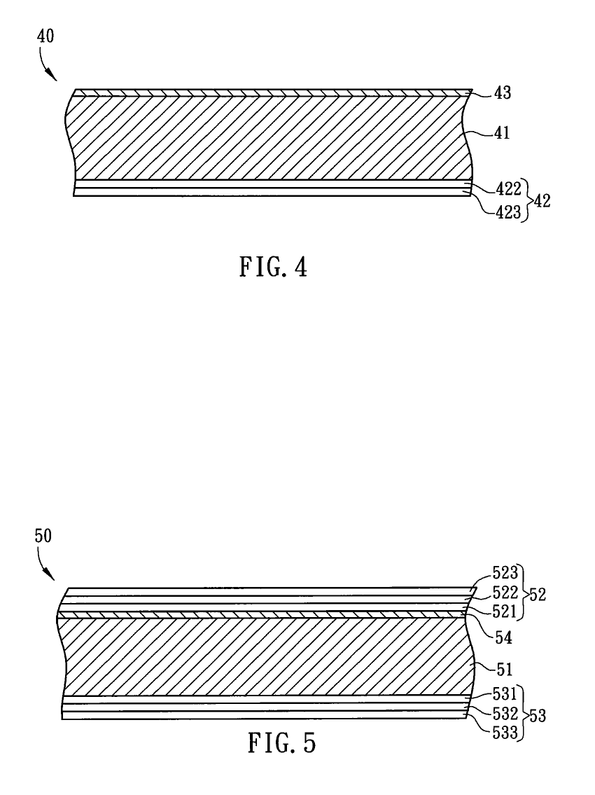

Please refer to FIG. 4. Another casing 40 of the electronic device 1 includes a photoelectric conversion film 42 and a casing body 41. The difference between this embodiment and the above embodiments is that the photoelectric conversion film 42 does not include a first electrode layer and the casing body 41 is used as the first electrode layer. In this embodiment, the casing body 41 is made of a transparent and conductive material, such as ITO, ZnO, or SnO₂, and it is used as a positive electrode. The photoelectric conversion film 42 includes a photoelectric conversion layer 422 and a second electrode layer 423. The photoelectric conversion layer 422 is located between the casing body 41 and the second electrode layer 423. In addition, the casing 40 further includes an insulating layer 43 disposed at one side of the casing body 41 to prevent users from touching the casing body 41 to get an electric shock. In addition, the insulating layer 43 can include an anti-reflecting material used as an anti-reflecting layer disposed on the casing body 41 to improve light transmittance and utilization of the light.

A Fifth Embodiment

Please refer to FIG. 5. Another casing 50 of the electronic device 1 includes a photoelectric conversion film 52, another photoelectric conversion film 53, and a casing body 51. In this embodiment, the casing body 51 is made of a transparent metal material and is used as a base plate of the photoelectric conversion films 52, 53. The photoelectric conversion films 52, 53 are formed at two sides of the casing body 51. The photoelectric conversion film 52, 53 includes a first electrode layer 521, 531, a photoelectric conversion layer 522,532, and a second electrode layer 523, 533. In this embodiment, the structures, materials, and manufacturing methods of the photoelectric conversion films 52, 53 are described in detail in the photoelectric conversion film 12 provided by the first embodiment. Therefore, they are not described for a concise purpose.

In this embodiment, the casing 50 further includes an anti-reflecting layer 54 disposed between the photoelectric conversion film 52 and the casing body 51. Thus, the light which is not absorbed by the photoelectric conversion film 52 passes through the casing body 51 and then reaches the photoelectric conversion film 53. Thereby, the light is reused, and the photoelectric conversion effect is improved.

To sum up, in the electronic device and the casing thereof according to the embodiment of the invention, the casing body is used as a base plate and the photoelectric conversion film having the organic material is formed at the casing body. Since the photoelectric conversion film includes the organic material, the photoelectric conversion film can be formed at one side or two sides of the casing body by a low temperature and simple manufacturing process such as printing, spreading, spraying, sputtering, evaporating, transfer printing, or a combination thereof. Thus, the casing of the electronic device is directly used as a photoelectric element, further to simplify the manufacturing process and to reduce manufacturing cost. In addition, since the casing body of the casing is used as a base plate of the photoelectric conversion film, a base plate originally needed can be omitted, further to reduce the cost and to decrease thickness of the casing.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A casing of an electronic device comprising:
a photoelectric conversion film having an organic material; and
a casing body, the photoelectric conversion film formed at the casing body.

2. The casing according to claim 1, wherein the casing body is transparent to light or lightproof.

3. The casing according to claim 1, wherein the casing body is made of plastic, ceramics, glass, quartz, metal, alloy, or a combination thereof.

4. The casing according to claim 1, wherein the casing body includes a circuit board.

5. The casing according to claim 1, wherein the photoelectric conversion film includes a first electrode layer, a second electrode layer, and a photoelectric conversion layer located between the first electrode layer and the second electrode layer.

6. The casing according to claim 5, wherein the first electrode layer is located on the casing body.

7. The casing according to claim 5, wherein the photoelectric conversion layer is a single layer or a double layer made of a donor material and an acceptor material, the donor material and the acceptor material including the organic polymer.

8. The casing according to claim 7, wherein the organic material includes an organic polymer, an organic molecule, a dye, or a combination thereof.

9. The casing according to claim 8, wherein the organic polymer is selected from the group consisting of poly p-phenylene vinylene, polythiophene, polypyrrole, polyaniline, poly 3-octylthiophene (P3OT), and derivative thereof.

10. The casing according to claim 8, wherein the dye is selected from the group consisting of an organic photosensitive dye including ruthenium complex series, phthalocyanine series, porphyrin series, chlorophyll and other derivative dyes.

11. The casing according to claim 7, wherein the donor material and the acceptor material include an inorganic material.

12. The casing according to claim 11, wherein the inorganic material includes TiO₂, Nb₂O₅, CdS, or a derivative of C₆₀.

13. The casing according to claim 5, wherein the photoelectric conversion film further has an electron hole conducting layer or an electron conducting layer contacting the photoelectric conversion layer.

14. The casing according to claim 1, wherein the photoelectric conversion film is formed at one side or two sides of the casing body by printing, spreading, spraying, sputtering, evaporating, transfer printing, or a combination thereof.

15. The casing according to claim 1, further comprising an anti-reflecting layer disposed at the photoelectric conversion film, at the casing body, or between the photoelectric conversion film and the casing body.

16. The casing according to claim 1, further comprising an electronic element disposed in the casing.

17. The casing according to claim 16, wherein the photoelectric conversion film and the electronic element are disposed at two sides of the casing body respectively, and electrically connected with each other.
